(19) United States
(12) Patent Application Publication
(10) Pub. No.: US 2023/0162985 A1
(43) Pub. Date: May 25, 2023

(54) METHOD FOR INCREASING OXYGEN CONTENT IN TMAH ETCHING

(71) Applicant: Shanghai Huali Integrated Circuit Corporation, Shanghai (CN)

(72) Inventors: Ying Wang, Shanghai (CN); Chunwei Wang, Shanghai (CN); Yi Yang, Shanghai (CN)

(21) Appl. No.: 17/946,465

(22) Filed: Sep. 16, 2022

(30) Foreign Application Priority Data
Nov. 25, 2021 (CN) 202111409044.6

(51) Int. Cl. H01L 21/306

(52) U.S. Cl. CPC H01L 21/30604

(57) ABSTRACT

A method for increasing oxygen content during TMAH etching includes using a wet etching machine, which has a liquid outlet of TMAH pipeline and a liquid outlet of TMAH return pipeline, both are connected to a mixed liquid tank, and a liquid inlet of TMAH return pipeline is connected to a return tank. The method includes: introducing nitrogen gas into the return tank containing TMAH, so as to reduce the oxygen content of TMAH in the return tank; introducing TMAH into the mixed liquid tank via the liquid outlet of the TMAH pipeline; introducing the TMAH in the return tank into the mixed liquid tank via the liquid outlet of the TMAH return pipeline. The method keeps the oxygen concentration in the mixed tank stable, so as to stabilize the TMAH etching rate, for a better sigma shaped silicon trench.

### CROSS-REFERENCES TO RELATED APPLICATIONS

This application claims the priority to Chinese patent application No. CN 202111409044.6, filed on Nov. 25, 2021 at CNIPA, and entitled “METHOD FOR INCREASING OXYGEN CONTENT IN TMAH ETCHING”, the disclosure of which is incorporated herein by reference in entirety.

### TECHNICAL FIELD

The present application relates to the technical field of semiconductors, in particular to a method for increasing the oxygen content in Tetramethylammonium hydroxide (TMAH) etching.

### BACKGROUND

In the process of processing and manufacturing wafers, when a specific amount of germanium is added to silicon, the lattice constant of silicon germanium (SiGe) becomes greater than that of pure silicon, thus producing compressive stress in source and drain areas. The process forming sigma shaped SiGe source and drain typically includes four steps. A SiGe hard mask defines an etching boundary for a dry etching process first followed by a wet etching process, the two etchings jointly form sigma shaped trenches, then silicon and germanium are deposited into the sigma shaped trenches.

Three chemical substances are currently used in tetramethylammonium hydroxide (TMAH) wet etching, wherein Dilute Hydrofluoric Acid (DHF) functions to remove a native oxide on the Si surface, TMAH functions to complete etching of silicon, and Standard Clean 1 (SC1) functions to remove particulate pollutants. TMAH achieves different etching rates regarding three crystal orientations of silicon. The etching rate regarding the <111> crystal orientation is much less than the etching rates regarding the other two crystal orientations, thereby forming the sigma shape. However, different oxygen contents in TMAH have different impacts on the TMAH etching rate.

Therefore, it is necessary to propose a new method to solve the above problem.

### BRIEF SUMMARY

In view of the above defect in the prior art, the present application provides a method for increasing the oxygen content in TMAH etching, so as to solve the problem of a poor sigma shape caused by different TMAH etching rates in the prior art.

The present application provides a method for increasing the oxygen content in TMAH etching, at least including:

step 1, providing a wet etching machine, the wet etching machine including a TMAH pipeline and a TMAH return pipeline, wherein a liquid outlet of the TMAH pipeline and a liquid outlet of the TMAH return pipeline lead to a mixed liquid tank, and a liquid inlet of the TMAH return pipeline is connected to a return tank;

step 2, introducing nitrogen into the return tank containing TMAH, so as to reduce the oxygen content of the TMAH in the return tank;

step 3, introducing TMAH into the mixed liquid tank via the liquid outlet of the TMAH pipeline, so that the introduction of the TMAH into the mixed liquid tank lasts for a first time period; and

step 4, introducing the TMAH in the return tank into the mixed liquid tank via the liquid outlet of the TMAH return pipeline, so that the introduction of the TMAH into the mixed liquid tank lasts for a second time period, making oxygen concentration of TMAH in the mixed liquid tank 7.8-8.2 in the range of ppm.

In some examples, the first time period in step 3 is 60 seconds.

In some examples, the second time period in step 4 is 10 seconds.

In some examples, a flow rate of the TMAH introduced into the mixed liquid tank via the liquid outlet of the TMAH pipeline in step 3 is 300 ml/min.

In some examples, a flow rate of the TMAH introduced into the mixed liquid tank via the liquid outlet of the TMAH return pipeline in step 4 is 6000 ml/min.

In some examples, the amount of the TMAH in the mixed liquid tank in step 4 is 40 L.

In some examples, before step 1, the method further includes wet etching of silicon using DHF, wherein a time of the etching using the DHF is 60 seconds.

In some examples, a TMAH etching rate is 69 A/min-75 A/min.

As stated above, the method of the preset application has the following beneficial effects: in the present application, a nitrogen gas (N₂) pipeline is added to the return tank to fill the return tank with an N₂ atmosphere and reduce the oxygen content of the TMAH in the return tank, keeping the oxygen concentration in the mixed tank stable, keeping the TMAH etching stable, and thereby etching silicon to form a better sigma shape.

### BRIEF DESCRIPTION OF THE DRAWINGS

FIG. 1 shows a flowchart of a method for increasing the oxygen content in TMAH etching according to the present application.

### DETAILED DESCRIPTION OF THE DISCLOSURE

The embodiments of the present application are described below using specific examples, and those skilled in the art can easily understand other advantages and effects of the present application from the contents disclosed in the Description. The present application can also be implemented or applied using other different specific embodiments, and various details in the Description can also be modified or changed based on different viewpoints and applications without departing from the spirit of the present application.

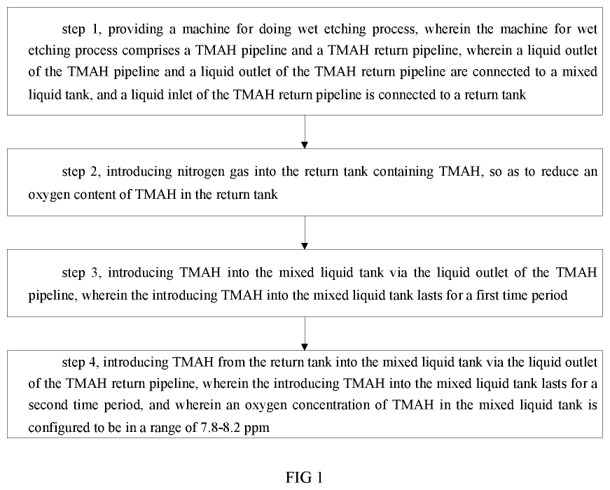

Please refer to FIG. 1. It should be noted that the drawings provided in this embodiment are only used to illustrate the basic concept of the present application in a schematic way, so the drawings only show the components related to the present application rather than being drawn according to the number, shape and size of the components in actual implementation. The type, number and proportion of various components can be changed randomly during actual implementation, and the layout of components may be more complicated.

Referring to FIG. 1, FIG. 1 is a flowchart of a method for increasing the oxygen content in TMAH etching according to the present application, at least including the following steps.

Step 1. A wet etching machine is provided, the wet etching machine includes a TMAH pipeline and a TMAH return pipeline, wherein a liquid outlet of the TMAH pipeline and a liquid outlet of the TMAH return pipeline lead to a mixed liquid tank, and a liquid inlet of the TMAH return pipeline is connected to a return tank. That is, the wet etching machine provided in step 1 can perform wet etching of silicon on a wafer by means of TMAH, and the etching is used to form a sigma trench between two gates of PFETs.

Step 2. Nitrogen gas is introduced into the return tank containing TMAH, so as to reduce the oxygen content of the TMAH in the return tank. In this embodiment of the present application, the return tank is connected to a nitrogen pipeline. In step 2, the nitrogen pipeline is connected to the return tank, and the introduction of the nitrogen can reduce the oxygen content of the TMAH in the return tank.

Step 3. TMAH is introduced into the mixed liquid tank via the liquid outlet of the TMAH pipeline, so that the introduction of the TMAH into the mixed liquid tank lasts for a first time period.

In this embodiment of the present application, the first time period in step 3 is 60 seconds. That is, in this embodiment, in step 3, the TMAH is introduced into the mixed liquid tank via the liquid outlet of the TMAH pipeline, so that the introduction of the TMAH into the mixed liquid tank lasts for 60 seconds.

In this embodiment of the present application, a flow rate of the TMAH introduced into the mixed liquid tank via the liquid outlet of the TMAH pipeline in step 3 is 300 ml/min.

Step 4. The TMAH in the return tank is introduced into the mixed liquid tank via the liquid outlet of the TMAH return pipeline, so that the introduction of the TMAH into the mixed liquid tank lasts for a second time period, making oxygen concentration of TMAH in the mixed liquid tank in the range of 7.8-8.2 ppm.

In this embodiment of the present application, the second time period in step 4 is 10 seconds. That is, in this embodiment, in step 4, the TMAH in the return tank is introduced into the mixed liquid tank via the liquid outlet of the TMAH return pipeline, so that the introduction of the TMAH into the mixed liquid tank lasts for 10 seconds, making the oxygen concentration of TMAH in the mixed liquid tank reach the range of 7.8-8.2 ppm.

In this embodiment of the present application, a flow rate of the TMAH introduced into the mixed liquid tank via the liquid outlet of the TMAH return pipeline in step 4 is 6000 ml/min.

In this embodiment of the present application, the amount of the TMAH in the mixed liquid tank in step 4 is 40 L.

In this embodiment of the present application, before step 1, the method further includes wet etching of silicon using DHF, wherein a time of the etching using the DHF is 60 seconds. The DHF functions to remove a native oxide on the surface of the wafer.

In this embodiment of the present application, an etching rate of etching silicon using TMAH is in the range of 69 A/min-75 A/min.

As stated above, in the present application, a N₂ pipeline is added to the return tank to fill the return tank with an N₂ atmosphere and reduce the oxygen content of the TMAH in the return tank, keeping the oxygen concentration in the mixed tank stable, keeping the TMAH etching stable, and thereby etching silicon to form a better sigma shape. Therefore, the present application effectively overcomes various defects in the prior art and has high industrial utilization value.

The above embodiment merely illustrates the principle and effect of the present application, rather than limiting the present application. Anyone skilled in the art can modify or change the above embodiment without departing from the spirit and scope of the present application. Therefore, all equivalent modifications or changes made by those with ordinary knowledge in the art without departing from the spirit and technical idea disclosed in the present application shall still be covered by the claims of the present application.

What is claimed is:

1. A method for increasing an oxygen content during tetramethylammonium hydroxide (TMAH) etching, comprising:
step 1, providing a machine for doing wet etching process, wherein the machine for wet etching process comprises a TMAH pipeline and a TMAH return pipeline, wherein a liquid outlet of the TMAH pipeline and a liquid outlet of the TMAH return pipeline are connected to a mixed liquid tank, and a liquid inlet of the TMAH return pipeline is connected to a return tank;
step 2, introducing nitrogen gas into the return tank containing TMAH, so as to reduce an oxygen content of TMAH in the return tank;
step 3, introducing TMAH into the mixed liquid tank via the liquid outlet of the TMAH pipeline, wherein the introducing TMAH into the mixed liquid tank lasts for a first time period; and
step 4, introducing TMAH from the return tank into the mixed liquid tank via the liquid outlet of the TMAH return pipeline, wherein the introducing TMAH into the mixed liquid tank lasts for a second time period, and wherein an oxygen concentration of TMAH in the mixed liquid tank is configured to be in a range of 7.8-8.2 ppm.

2. The method for increasing the oxygen content during the TMAH etching according to claim 1, wherein the first time period in step 3 is configured to be 60 seconds.

3. The method for increasing the oxygen content during the TMAH etching according to claim 1, wherein the second time period in step 4 is configured to be 10 seconds.

4. The method for increasing the oxygen content during the TMAH etching according to claim 1, wherein a flow rate of the TMAH introduced into the mixed liquid tank via the liquid outlet of the TMAH pipeline in step 3 is configured to be 300 ml/min.

5. The method for increasing the oxygen content during the TMAH etching according to claim 1, wherein a flow rate of the TMAH introduced into the mixed liquid tank via the liquid outlet of the TMAH return pipeline in step 4 is configured to be 6000 ml/min.

6. The method for increasing the oxygen content during the TMAH etching according to claim 1, wherein an amount of the TMAH in the mixed liquid tank in step 4 is configured to be 40 L.

7. The method for increasing the oxygen content during the TMAH etching according to claim 1, before step 1, wherein the method further comprises an wet etching process on a silicon substrate by applying a diluted hydrogen fluoride acid (DHF), wherein a time of the wet etching process applying the DHF is configured to be 60 seconds.

8. The method for increasing the oxygen content during the TMAH etching according to claim 1, wherein a TMAH etching rate is configured in a range of 69 A/min-75 A/min.
